(19) United States
(12) Patent Application Publication
(10) Pub. No.: US 2024/0357947 A1
(43) Pub. Date: Oct. 24, 2024

(54) ELECTRONIC CIRCUIT WITH A SUPERCONDUCTING ELECTRONIC CIRCUIT UNIT

(71) Applicant: Infineon Technologies AG, Neubiberg (DE)

(72) Inventors: Jochen BRAUMÜLLER, Otterfing (DE); Florian BRANDL, Maxhütte-Haidhof (DE); Michael KIRSCH, Regensburg (DE); Wolfgang RABERG, Sauerlach (DE); Nicolas ARLT, München (DE); Jash BANKER, Unterhaching (DE); Patrick HANEKAMP, Laaber (DE)

(21) Appl. No.: 18/635,621

(22) Filed: Apr. 15, 2024

(30) Foreign Application Priority Data
Apr. 24, 2023 (DE) 102023110379.2

(51) Int. Cl. H10N 60/85; G06N 10/40; H10N 60/80

(52) U.S. Cl. CPC H10N 60/85; G06N 10/40; H10N 60/805

(57) ABSTRACT

An electronic circuit includes a substrate and a superconducting electronic circuit unit which is constructed on the substrate. The superconducting electronic circuit unit includes a capacitor with parallel plates opposite one another and a crystalline capacitor dielectric arranged between the parallel plates.

### CROSS-REFERENCE TO RELATED APPLICATION

This application claims priority to German Patent Application No. 102023110379.2 filed on Apr. 24, 2023, the content of which is incorporated by reference herein in its entirety.

### TECHNICAL FIELD

This disclosure relates generally to the field of electronic circuits and in particular to electronic circuits with a superconducting electronic circuit unit.

### BACKGROUND

Electronic circuits which contain a superconducting electronic circuit unit are used in various fields in technology. Superconducting electronic circuit units may be, for example, a platform for the realization of quantum hardware, which is able to perform calculations and to this end operate using one or more superconducting quantum bits (qubits) (for example quantum computers). Also known are transistor-like devices such as single flux quantum devices (SFQ), which are based on superconducting electronic circuit units.

A source of faults in superconducting electronic circuit units is dielectric loss. This occurs when the electric fields of the electronic circuit unit penetrate a dielectric material that contains microscopic defects-so-called two-level systems (TLS). The dipole moment of the TLS is coupled to the electric field of the circuit unit, which leads to problems—in the case of qubits, for example, to a reduction in their service life due to spontaneous relaxation of qubit excitations. Since individual low-energy excitations are used to encode quantum states, such TLS interactions have a significant impact on the performance of the superconducting electronic circuit unit (for example qubit) and are therefore decisive for whether the superconducting electronic circuit unit is suitable for use as quantum hardware.

### SUMMARY

According to one aspect of the disclosure, an electronic circuit includes a substrate and a superconducting electronic circuit unit which is constructed on the substrate. The superconducting electronic circuit unit includes a capacitor with parallel plates opposite one another and a crystalline capacitor dielectric between the parallel plates.

According to another aspect of the disclosure, a method for producing an electronic circuit includes providing a substrate. A first plate of a capacitor is formed above a first main surface of the substrate. A second plate of the capacitor which is opposite the first plate and parallel to the first plate is formed, wherein a crystalline capacitor dielectric is present between the parallel plates. A superconducting electronic circuit unit which includes the capacitor is formed on the substrate.

### BRIEF DESCRIPTION OF THE DRAWINGS

The elements in the drawings are not necessarily true to scale with respect to one another. The same reference signs refer to corresponding similar parts. The features of the various implementations illustrated may be combined, provided they are not mutually exclusive, and/or they may be selectively omitted if they are not described as absolutely necessary. The implementations are illustrated in the drawings and are explained in more detail by way of example in the following description.

FIG. 1 shows a circuit diagram of an example of a superconducting electronic circuit unit having a capacitor.

FIG. 2 shows a partial sectional view of a conventional (lateral) implementation of the capacitor of the superconducting electronic circuit unit of FIG. 1 in an electronic circuit.

FIG. 3 shows a schematic plan view of an example of an electronic circuit having a superconducting electronic circuit unit which is constructed on a substrate and which is implemented with lateral capacitors.

FIG. 4 shows a partial sectional view of an example implementation of the capacitor of the superconducting electronic circuit unit of FIG. 1 in accordance with the present disclosure in an electronic circuit.

FIG. 5 shows a schematic sectional illustration of a silicon-on-insulator (SOI) substrate after structuring of a silicon layer above an oxide layer.

FIG. 6 shows a schematic sectional illustration of the SOI substrate of FIG. 5 after forming a first plate of a capacitor above the SOI substrate.

FIG. 7 shows a schematic sectional illustration of the SOI substrate of FIG. 6 after removing substrate material below the first plate.

FIG. 8 shows a schematic sectional illustration of the SOI substrate of FIG. 7 after removing the oxide layer of the SOI substrate in an area below the first plate.

FIG. 9 shows a schematic sectional illustration of an example of an electronic circuit after producing a second plate of the capacitor on the SOI substrate of FIG. 8.

FIG. 10 shows a schematic sectional illustration of an example of an electronic circuit having a superconducting electronic circuit unit which is constructed on a thinned substrate.

FIG. 11 shows a schematic sectional illustration of an example of an electronic circuit having a superconducting electronic circuit unit which is constructed on a thinned substrate, wherein the thinned substrate is applied to a carrier.

### DETAILED DESCRIPTION

In this description, the terms “electrically connected” or “electrically coupled” or similar terms are not to be understood as meaning that the elements are in direct contact with one another; intermediate elements may be provided between the “electrically connected” or “electrically coupled” elements. According to the disclosure, however, the above and similar terms may optionally also have the specific meaning that the elements are in direct galvanic contact, that is to say no intermediate elements are provided between the “electrically connected” or “electrically coupled” elements.

Furthermore, the terms “above” or “below” may be used here in relation to a part, element or material layer that is formed or located or arranged “above” or “below” a surface to mean that the part, element or material layer is located (for example placed, formed, arranged, deposited, etc.) “directly on” or “directly below”, that is to say in direct contact with, the surface in question. However, the term “above” or “below” used in relation to a part, element or material layer that is formed or located “above” or “below” a surface may also be used here to mean that the part, element or material layer is located (for example placed, formed, arranged, deposited, etc.) “indirectly on” or “indirectly below” the surface in question, with one or more additional parts, elements or layers being arranged between the surface in question and the part, element or material layer.

An electronic circuit according to the present disclosure comprises a substrate and a superconducting electronic circuit unit which is constructed on the substrate. FIG. 1 shows a circuit diagram of an example of a superconducting electronic circuit unit 100.

The superconducting electronic circuit unit 100 has a plate capacitor 110 and at least one further circuit unit element 150. Both the plate capacitor 110 and the circuit unit element 150 are made of one or more superconductive materials. This means that the plate capacitor 110 and the at least one circuit unit element 150 can be brought into the superconducting state and are superconducting during operation of the circuit unit 100.

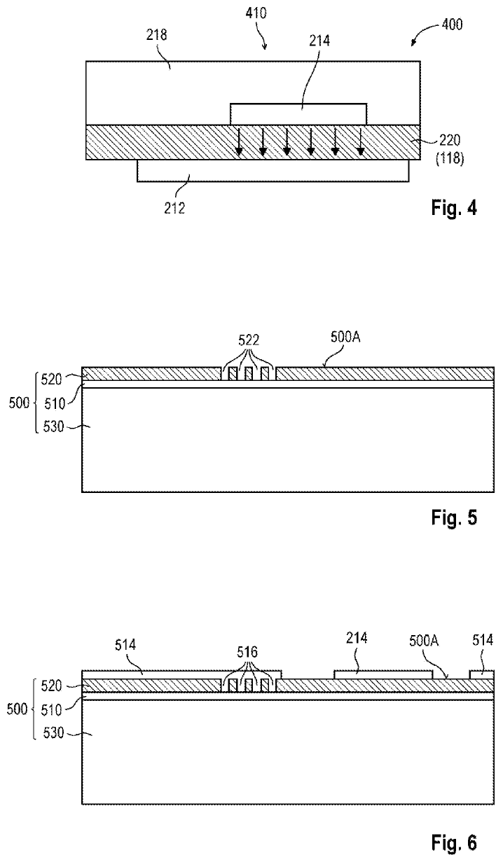

The circuit diagram of FIG. 1 is also to be understood structurally with respect to the plate capacitor 110. That is to say, according to the present disclosure (see also FIG. 4), the plate capacitor 110 in structural terms has two superconducting plates (electrodes) 112, 114 which are opposite one another and arranged parallel to one another. A capacitor dielectric 118 is located between the plates 112, 114. In particular, the entire space between the two plates 112, 114 can be filled with the capacitor dielectric 118.

According to the present disclosure (see also FIG. 4), the capacitor dielectric 118 consists of a crystalline material. In particular, the capacitor dielectric 118 is a crystalline, highly resistive and low-loss dielectric. For example, the capacitor dielectric 118 may consist of (intrinsic) crystalline silicon or of another highly resistive, low-loss dielectric such as sapphire, for example.

As will be explained in more detail below, the capacitor dielectric 118 may be a material layer which is not formed by deposition of a dielectric material on one of the plates 112, 114, but is part of a crystalline substrate which implements the superconducting circuit unit 100. In this respect, the capacitor dielectric 118 may be a monocrystalline layer which has not been produced by epitaxial growth. However, it may also be conceivable to realize the capacitor dielectric 118 as an epitaxial layer (for example Si epitaxial layer), provided that such an epitaxial layer allows the (high) requirements for the freedom from dielectric losses.

The superconducting circuit unit 100 may be, for example, a superconducting quantum circuit unit. A superconducting quantum circuit unit may be used as a quantum computer. FIG. 1 shows a specific implementation of a superconducting electronic circuit unit 100 which realizes a qubit. The circuit unit element 150 may be formed in this case and others by a Josephson contact. The superconducting electronic circuit unit 100 is a specific example of superconducting electronic circuit units which are referred to as Josephson qubits.

In other words, superconducting electronic circuit units can be used as a solid state concept for the implementation of quantum computers. Superconducting electronic circuit units such as the circuit unit 100, for example, may include or constitute a resonant circuit which, for example, realizes an anharmonic quantum oscillator as a result of the Josephson contact 150. Other examples of electronic components containing a superconducting electronic circuit unit include single flux quantum (SFQ) components, for example. These are classic logic components in which voltage pulses generated by Josephson contacts in the superconducting electronic circuit unit are used to encode, process and transmit digital information.

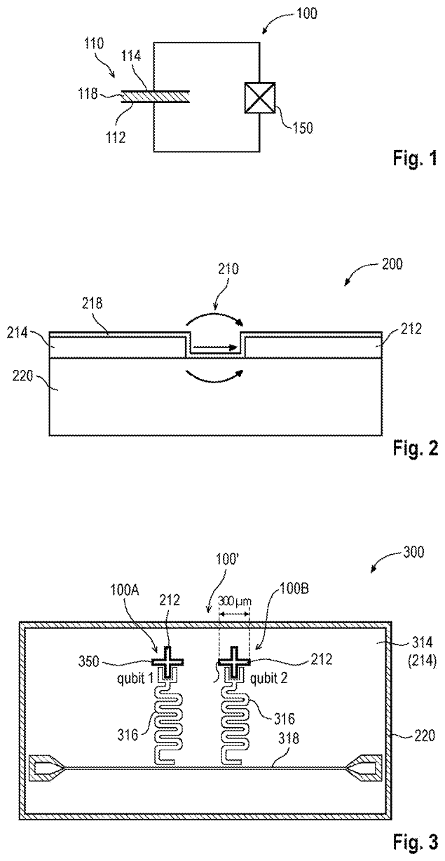

FIG. 2 shows a partial sectional view of a conventional, lateral implementation of a capacitor of a superconducting electronic circuit unit 100 in an electronic circuit 200. The electronic circuit 200 comprises a substrate 220, the capacitor 210 which is constructed on the substrate 220, and an (optional) dielectric 218. The capacitor 210 is a lateral capacitor which is realized in a planar geometry, that is to say the capacitor 210 has plates (capacitor electrodes) 212, 214 which (unlike the plate capacitor 110 illustrated in FIG. 1) are arranged next to one another in the same plane.

As can be seen in FIG. 2, the electric field lines (arrows) penetrate the substrate 220 below the plates 212, 214 and an area between and above the plates 212, 214. In this area, there may be a vacuum, wherein usually lossy dielectrics are located on the surfaces between and above the plates 212, 214 (illustrated by the lossy dielectric 218). In practice, the dielectric 218 is, for example, silicon oxide or oxide layers which form on the superconducting material of the plates 212, 214 and are inevitable when the electronic circuit 200 is exposed to air.

In this case, dipole moments of microscopic defects (TLS) of the dielectric 218 couple to the electric field between the plates 212, 214, which causes dielectric losses which significantly reduce the lifetime of quantum states in the superconducting electronic circuit unit 100 of the electronic circuit 200.

One option to limit the electric field strength in such lossy dielectric areas is to increase the distances between the plates 212, 214 in such electronic circuits 200. However, this increases the base area of capacitor 210 and thus increases the overall size of the electronic circuit 200. In addition, the field lines of the capacitors 210 are poorly limited in terms of space, which may lead to undesired interactions. This impairs the scalability of the superconducting circuit unit in the lateral dimension. Furthermore, the scalability of the integration scheme to a multilayer process is severely limited since the area above the field range of the capacitors 210 cannot be filled with planarizing dielectrics (due to unwanted dielectric losses) as is customary in semiconductor manufacturing.

FIG. 3 shows a schematic plan view of an example of a conventional electronic circuit 300 having a superconducting electronic circuit unit 100′ which is constructed on a substrate 220. The superconducting electronic circuit unit 100′ implements a quantum circuit unit. In the specific example of FIG. 3, two superconducting qubits (qubit 1 and qubit 2) are formed by the superconducting electronic circuit unit 100′. For example, each of the qubits can be realized by non-linear electrical resonant circuits 100A or 100B. The non-linear electrical resonant circuits 100A and 100B can be realized, for example, having a superconducting electronic circuit unit 100 according to the circuit diagram of FIG. 1.

The non-linear electrical resonant circuits 100A, 100B each contain a capacitor electrode 212 and a Josephson contact 350. The capacitor electrode 212 may, for example, be formed as an X-shaped island which is structured out of a superconducting material layer 314. The other capacitor electrode 214 may be formed by the superconducting material layer 314 itself.

In addition, further circuit unit elements 150 of the electronic circuit 300 may be formed in the superconducting material layer 314 by way of structuring. For example, FIG. 3 shows readout resonators 316 which are structured out of the superconducting material layer 314 and are each capacitively coupled to a qubit. In addition, a transmission line 318 is shown, which is capacitively coupled to the readout resonators 316.

In other words, a superconducting electronic circuit unit 100′ may comprise, for example, one or more qubits (realized, for example, by the non-linear electrical resonant circuits 100A and 100B) and a readout circuit, where the latter may comprise, for example, the readout resonators 316 and/or the transmission line 318. The readout circuit is in this case coupled to the qubits (that is to say the non-linear electrical resonant circuits 100A, 100B) via one or more capacitors (in this example, the capacitors between the readout resonators 316 and the capacitor electrode 212) and/or may contain capacitors themselves (in this case, for example, the capacitors between the readout resonators 316 and the transmission line 318).

All of the capacitors contained in the electronic circuit 300 are configured in FIG. 3 as lateral capacitors. The following text presents implementation concepts for circuits which implement capacitors of superconducting electronic circuit units in a vertical design.

FIG. 4 shows a partial sectional view of an example implementation of a capacitor 410 of the superconducting electronic circuit unit of an electronic circuit 400. Like the electronic circuit 200, the electronic circuit 400 has a substrate 220 and a superconducting electronic circuit unit which is constructed on the substrate 220, as shown, for example, in FIGS. 1 and/or 3 (electronic circuit unit 100 and 100′). In this case, the electronic circuit 400 differs from the electronic circuit 200 in that at least one capacitor 210 is configured as a plate capacitor with parallel plates 212, 214 which are opposite one another and between which a crystalline capacitor dielectric 118 is present.

In other words, the capacitor 410 has the features of the capacitor 110 (FIG. 1), wherein the plates 112, 114 are formed from the plates 212, 214 and the capacitor dielectric 118 is formed, for example, from a part or a portion of the substrate 220.

The capacitor dielectric 118 realized in FIG. 4, for example, as part of the substrate 220 may comprise, for example, intrinsic crystalline silicon or sapphire or another crystalline and/or low-loss dielectric or consist thereof.

As can be seen from FIG. 4, the electric field lines (arrows) are limited to the capacitor dielectric 118, that is to say the electric field does not penetrate into the region of the lossy dielectric 218, or at least penetrates to a much lesser extent than in the case of the lateral capacitor 210 (FIG. 2). As a result, significantly lower dielectric losses can be achieved.

The implementation of the capacitor 410 shown in FIG. 4 may be applied to any capacitor of the superconducting electronic circuit unit 100, 100′. For example, in the electronic circuit 300 shown in FIG. 3, the capacitive coupling between the capacitor electrodes 212, 214 of the qubits and/or the capacitive coupling between the non-linear electrical resonant circuits 100A, 100B (qubits) and the readout circuit (for example via the capacitors between the capacitor electrode 212 and the readout resonator 316) and/or a capacitor within the readout circuit (for example the capacitive coupling between the readout resonator 316 and the transmission line 318) may be realized by a capacitor 410 according to FIG. 4.

The implementation of a capacitor 410 according to FIG. 4 in a superconducting electronic circuit unit 100, 100′ enables the following advantages over the implementation of lateral capacitors 210 according to FIG. 2:

As already mentioned, the vertical implementation of a capacitor 410 reduces the dielectric losses since the field lines do not pass through lossy interfaces. In this case, the surfaces of the capacitor dielectric 118 can be cleaned prior to the production of the plates (capacitor electrodes) 212, 214 in such a way that reoxidation is prevented in order to ensure a high-purity metal-dielectric interface. This interface may seal itself by producing the plates 212, 214 before the electronic circuit 400 is exposed to air (in-situ process).

In addition, a reduction in parasitic crosstalk within the electronic circuit 400 is made possible by the significant spatial limitation of the electric fields. In contrast to the attenuation of the electric fields in a large dielectric volume above the substrate 220 in a planar circuit layout (see FIGS. 2 and 3), the electric fields in the capacitor 410 in a vertical parallel plate design are limited to the small, high-quality dielectric volume between the plates 212, 214.

The vertical design of the capacitor 410 also enables the size of the base area of the electronic circuit 400 to be reduced. The capacitor 410 can be realized with the same capacitance with a much smaller base area than the capacitor 210 in a planar design. For example, the distance between the parallel plates 212, 214 of the parallel plate capacitor 410 may be in the order of magnitude of 2 μm, while the distance between the capacitor electrodes 212, 214 of the lateral plate capacitor 210 with comparable capacitance is in the order of magnitude of 30 μm. Consequently, the overlap area (that is to say the total size) of a parallel plate capacitor 410 is significantly smaller than the total electrode size of a lateral plate capacitor 210 with a comparable capacitance.

Furthermore, the vertical implementation of the capacitor 410 enables the provision of a superconducting circuit unit architecture which is compatible with a three-dimensional integration. Due to the field confinement and the encapsulation of the capacitor 410 from all sides, this realization enables a multilayer integration of superconducting electronic circuit units 100, 100′ in electronic circuits 300, 400.

In some examples, with the exception of the capacitor or capacitors 410, all of the components of the superconducting electronic circuit unit 100, 100′ may be arranged above a first main surface of the substrate 220. This is the case, for example, in the case of the electronic circuit 300, provided that the capacitors present there are partially or completely replaced by vertical parallel plate capacitors 410 according to FIG. 4. The remaining components (for example the Josephson contacts 350 and/or the readout resonators 316 and/or the transmission line 318) are formed in the superconducting material layer 314 which extends above the substrate 220. The superconducting material layer 314 consists of a superconducting material such as aluminum, niobium or tantalum, for example.

For example, the substrate 220 may be an SOI (silicon-on-insulator) substrate. FIGS. 5-9 show an example manufacturing process of an electronic circuit using an SOI substrate 500.

The SOI substrate 500 has a monocrystalline silicon layer 520 which is arranged above an oxide layer 510. The oxide layer 510 is located above a base substrate layer 530 which may consist of bulk silicon, for example. The buried oxide layer 510 is also referred to in technology as a BOX (Buried OXide). The layer thickness thereof is about 1 μm, for example.

The monocrystalline silicon layer 520 may have a thickness between 50 nm and 4 μm, for example. In the example illustrated here, the thickness of the monocrystalline silicon layer 520 is 2 μm, for example. Since this silicon layer 520 is provided to form the capacitor dielectric 118, smaller layer thicknesses enable a reduction in the lateral dimensions of the plate capacitor 110, 410. For example, the layer thickness of the monocrystalline silicon layer 520 may be equal to or less than 3 μm, 2 μm, 1 μm, 500 nm, 200 nm or 100 nm.

As described in more detail below, components of the superconducting electronic circuit unit 100, 100′, such as Josephson contacts, inductors, readout resonators and/or signal and routing lines, can be arranged on the top of the SOI substrate; see for example the components 350, 316, 318 of FIG. 3. These components are either not critical to dielectric losses or they do not generate electric fields that could cause dielectric loss. In this respect, they may be formed on a surface of the SOI substrate 500.

For example, the manufacturing process may include forming vias through the monocrystalline silicon layer 520. For this purpose, one or more openings (for example holes or trenches) 522 are generated in the monocrystalline silicon layer 520 and extend down to the top of the oxide layer 510. The oxide layer 510 may be used in this case as an etch stop layer.

After the (optional) generation of the openings 522, a cleaning step can be carried out. In this case, a first main surface 500A of the substrate 500 (which in this example is formed by the exposed surface of the monocrystalline silicon layer 520) and the inner surfaces of the openings 522 (if present) have been cleaned to remove all silicon oxides or other residues on the silicon surfaces and in particular on the first main surface 500A. For cleaning, the SOI substrate 500 may be subjected, for example, to an HF steam and/or an Ar descum sputtering process and/or a comparable suitable cleaning method.

The cleaning method can be carried out in situ, that is to say with an air seal and, for example, in vacuum.

According to FIG. 6, a superconducting material, such as niobium, aluminum or tantalum or the like, is then deposited in situ (that is to say without interrupting the air seal and/or the vacuum) on the first main surface 500A of the SOI substrate 500. The superconducting material layer 514 formed in the process corresponds to the superconducting material layer 314 of FIG. 3. The superconducting material fills the openings 522 and thereby forms the vias 516.

For example, the layer thickness of the superconducting material layer 514 may be between 50 nm and 500 nm. For example, the layer thickness may be equal to or less than 400 nm, 300 nm, 200 nm or 100 nm. However, layer thicknesses greater than 500 nm may also be realized.

Subsequently, the superconducting material layer 514 may be structured. The structuring can be carried out by lithography. Structuring the superconducting material layer 514 forms a first plate (capacitor electrode) 214 of the capacitor 410 (see FIG. 4). In addition, further components of the superconducting electronic circuit unit 100, 100′, such as Josephson contacts 350, readout resonators 316, transmission lines 318, etc., can be partially or completely formed in the structuring (see FIG. 3).

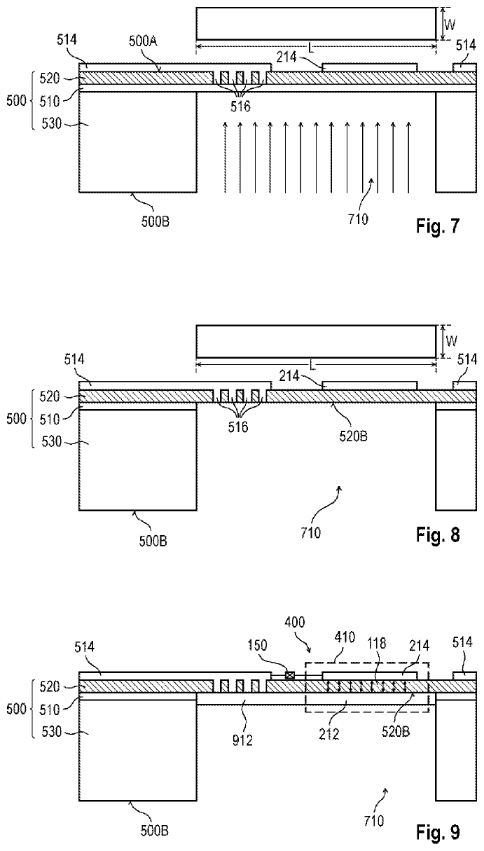

As shown in FIG. 9, the method for producing an electronic circuit 400 further comprises forming the second plate (capacitor electrode) 212 which is opposite the first plate 214 and parallel to the first plate 214. FIGS. 7-9 illustrate possible processes that may be carried out to form the second plate 212.

According to FIG. 7, substrate material can be removed from a second main surface 500B of the substrate 500 which is opposite the first main surface 500A of the substrate 500 in an area below the first plate 214. In this case, a recess 710 in the substrate 500 is formed on the second main surface 500B.

The removal of the substrate material can be carried out, for example, using an etching process (see arrows). The etching process may include a Bosch method, a wet etching method or another suitable etching method. The oxide layer 510 may be used, for example, as an etch stop for the rear etching process; see FIG. 7.

The depression 710 partially or completely overlaps the top plate 214. The upper part of FIG. 7 shows a top view of the recess 710. For example, the recess 710 may have a width W equal to or greater than the corresponding dimension of the first plate 214. Furthermore, the recess 710 may have a length L equal to or greater than the corresponding dimension of the first plate 214, for example.

In particular, the recess 710 may be dimensioned such that it also partially or completely overlaps with the openings 522.

For example, the width W may be 10 μm. For example, the length L may be 40 μm. These dimensions are variable and may depend, for example, on the dimensions of the first plate 214. For example, range limits of the width W and/or length L may be greater or smaller by a factor of 5 or 4 or 3 or 2 than the specified example width W=10 μm and/or the specified example length L=40 μm.

According to FIGS. 7 and 8, the removal of the substrate material may further comprise the removal of the oxide layer 510 in the area below the first plate 214. The oxide layer 510 may be removed, for example, by a wet etching method or by a physical dry etching method. Removing the oxide layer 510 in the recess 710 exposes a lower surface 520B of the monocrystalline silicon layer 520. Furthermore, the lower ends of the vias 516 may be exposed.

Subsequently, as already described above, an in-situ method for cleaning the lower surface 520B of the monocrystalline silicon layer 520 can be carried out. To avoid repetition, reference is made to the description above.

According to FIG. 9, a superconducting material is deposited within the recess 710. This produces a lower superconducting material layer 912. The superconducting material forms the second plate (capacitor electrode) 212. In addition, the superconducting material may form good galvanic contact with the vias 516. The deposition of the superconducting material may—as already described in FIG. 6—be carried out in situ, that is to say under an air seal and without interrupting the vacuum, for example. In this respect, the superconducting material of the second plate 212 can be deposited on a prepared lower surface 520B of the monocrystalline silicon layer 520 which is free of oxides or other residues.

The lower superconducting material layer 912 which is produced in the recess 710 comprises the plate 212. The lower superconducting material layer 912 may be formed (dimensioned) such that the second plate 212 which is formed from it completely overlaps the first plate 214. In other words, the capacitor 410 may be dimensioned such that the overlap area of the plates 212, 214 is given solely by the shape of the upper first plate 214. This ensures that the capacitor 410 is robust with respect to tolerances or lateral misalignments of the recess 710 (that is to say the rear side etching which produces the recess 710, for example).

The lower superconducting material layer 912 may be structured (not shown). For example, one or more lower second plates (capacitor electrodes) 212 may be produced from the lower superconducting material layer 912. In addition, one or more components (for example Josephson contact, inductor, readout resonator, transmission line, etc.) of the electronic circuit 400 may also be formed in the lower superconducting material layer 912 (not shown). The statements made with respect to the upper superconducting material layer 514 may correlate analogously to the lower superconducting material layer 912.

FIG. 9 furthermore shows a schematic illustration of a circuit unit element 150 which is formed between the upper first plate 214 and the structured superconducting material layer 514. For example, the circuit unit element 150 may contain or constitute a Josephson contact 350. In this case, the electronic circuit 400 contains a superconducting electronic circuit unit which is constructed on the substrate 500 and which, for example, may contain or correspond to a superconducting electronic circuit unit 100 of FIG. 1 or a superconducting electronic circuit unit 100′ of FIG. 3.

The in-situ cleaning methods described in relation to FIGS. 5 and 9 may be replaced or extended, for example, by ex-situ cleaning methods, which are temporally coupled to the subsequent deposition process in order to limit the reoxidation of the respective substrate surfaces 500A and 520B, respectively.

As already mentioned, the capacitors of other components than the qubit may also be realized as parallel plate capacitors.

The substrate 500 may also be a substrate other than an SOI substrate. For example, the substrate 500 may be replaced by a bulk silicon substrate or by a bulk sapphire substrate. In the case of a bulk silicon substrate, the production of the recess 710 may be achieved, for example, by an etching process with a defined depth.

As described by way of example in FIGS. 5 to 9, the first main surface 500A of the substrate 500 may be processed first and then the second main surface 500B. However, it is also possible that the second main surface 500B is processed first (see FIGS. 7 to 9) and then processing of the first main surface 500A (see FIGS. 5 and 6) is carried out.

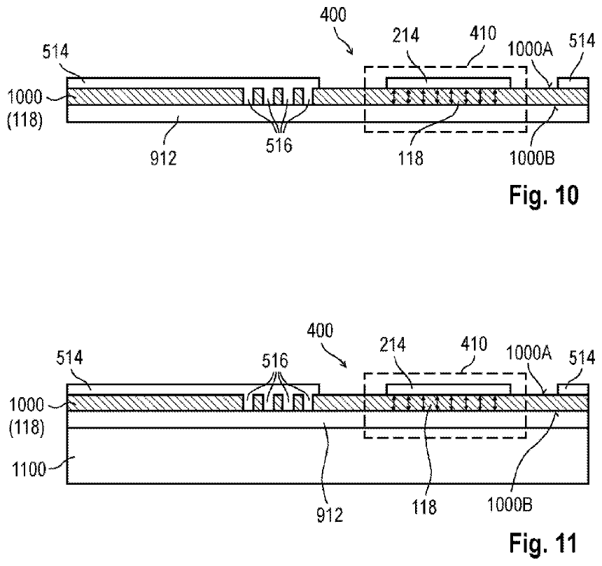

In other examples, the production of a recess 710 on the second main surface 500B (rear etching) may be omitted. The substrate 500 is replaced by a (typically much thinner) substrate 1000; see FIGS. 10 and 11. The substrate 1000 may, for example, be single-layer, that is to say consisting solely of a single material (for example intrinsic, monocrystalline silicon or sapphire or another low-loss dielectric). In this case, the thickness of the (for example single-layer) substrate 1000 may correspond to the thickness of the capacitor dielectric 220 (118).

For sufficient mechanical stability of the substrate 1000, the thickness of the substrate 1000 may, for example, be equal to or less than or greater than 10 μm or 20 μm or 30 μm. Since sapphire has a higher mechanical stability than silicon, capacitors 410 with a capacitor dielectric 118 of small thickness may, for example, consist of sapphire.

The statements made with respect to FIGS. 5 to 9 apply analogously to the electronic circuit 400 of FIGS. 10 and 11. In particular, as already described in relation to FIG. 9, the lower superconducting material layer 912 may be continuous (unstructured) or one or more lower second plates 212 may be structured out of this layer (not shown) and/or components or lines of the superconducting electronic circuit unit may be formed in the lower superconducting material layer 912 in a manner which is not illustrated.

The electronic circuit 400 may be realized, for example, in the form of a processed wafer (substrate 1000). For example, it may be transferred and mounted in a suitable housing or package (not shown) without further reinforcing structures or the like, that is to say as shown in FIG. 10.

FIG. 11 shows an example in which the substrate 1000 is attached to a carrier 1100 which faces the second main surface 1000B of the substrate 1000 to increase the mechanical stability. The carrier 1100 may be substantially thicker than the substrate 1000. For example, the thickness of the carrier 1100 may be equal to or greater than or less than 50 μm, 100 μm, 200 μm, 300 μm or 500 μm.

The carrier 1100 may consist of silicon or another low-loss dielectric (for example sapphire) or a lossy dielectric, such as, for example, glass, or it may contain same. Since the field lines are limited to the low-loss dielectric 118 which is formed by the substrate 1000, no special requirements with regard to the absence of dielectric loss are placed on the material of the carrier 1100.

A method for producing the electronic circuits 400 illustrated by FIG. 10 and FIG. 11 may comprise the following steps: First, as shown in FIGS. 5 and 6, the first main surface 1000A of a thick starting substrate is processed.

The starting substrate (for example wafer) is then turned and thinned on the back. The thinning of the starting substrate may be carried out, for example, using a grinding process and/or etching process. The second main surface 1000B and thus the (single-layer) substrate 1000 is formed by the thinning.

Subsequently, the lower superconducting material layer 912 is deposited on the second main surface 1000B of the substrate 1000 and optionally structured. In the example shown in FIG. 11, the carrier 1100 is then attached to facilitate the mechanical stability for the following method steps (in particular the transfer and installation of the electronic circuit 400 in a housing/package (not shown)). Since these method steps are critical with regard to the mechanical stability of the substrate 1000, a carrier 1100 may make it possible for the substrate 1000 to be realized to be thinner and/or from a less stable dielectric than is possible in the carrier-free variant according to FIG. 10.

### Aspects

The following aspects relate to other aspects of the disclosure:

Aspect 1 is an electronic circuit which comprises a substrate and a superconducting electronic circuit unit which is constructed on the substrate. The superconducting electronic circuit unit comprises a capacitor with parallel plates opposite one another and a crystalline capacitor dielectric arranged between the parallel plates.

In Aspect 2, the subject of Aspect 1 may optionally include that a part of the substrate forms the capacitor dielectric.

In Aspect 3, the subject of Aspect 1 or 2 may optionally include that the capacitor dielectric comprises crystalline silicon or sapphire.

In Aspect 4, the subject of any one of the preceding aspects may optionally include that the superconducting electronic circuit unit comprises a resonant circuit which comprises the capacitor.

In Aspect 5, the subject of any one of Aspects 1 to 3 may optionally include that the superconducting electronic circuit unit comprises a resonant circuit and an electronic readout circuit, wherein the resonant circuit and the electronic readout circuit are coupled via the capacitor.

In Aspect 6, the subject of Aspect 4 or 5 may optionally include that the resonant circuit contains a Josephson contact.

In Aspect 7, the subject of Aspect 6 may optionally include that the resonant circuit constitutes a qubit.

In Aspect 8, the subject of one of the preceding aspects may optionally include that, except for the capacitor, all of the components of the superconducting electronic circuit unit are arranged above a first main surface of the substrate.

In Aspect 9, the subject of one of the preceding aspects may optionally include that the substrate is an SOI substrate which comprises a silicon layer above an oxide layer, and the capacitor dielectric is formed by a part of the silicon layer.

Aspect 10 is a method for producing an electronic circuit, wherein the method comprises: providing a substrate; forming a first plate of a capacitor above a first main surface of the substrate; forming a second plate of the capacitor which is opposite the first plate and parallel to the first plate, wherein a crystalline capacitor dielectric is present between the parallel plates (e.g., the first plate and the second plate); and forming a superconducting electronic circuit unit on the substrate which comprises the capacitor.

In Aspect 11, the subject of Aspect 10 may optionally include that forming the second plate comprises: removing substrate material on a second main surface of the substrate which is opposite the first main surface of the substrate in an area below the first plate, wherein a recess is formed in the substrate on the second main surface; and producing the second plate in the recess. In other words, the subject of Aspect 10 may optionally include removing the substrate material on a second main surface of the substrate in an area below the first plate in order to form a recess in the substrate on the second main surface, wherein the second main surface is arranged opposite to the first main surface of the substrate.

In Aspect 12, the subject of Aspect 11 may optionally include that the substrate is an SOI substrate which comprises a silicon layer above an oxide layer, and the removal of substrate material comprises: removing the substrate material starting from the second main surface of the substrate in the area below the first plate; and removing the oxide layer in the area below the first plate.

In Aspect 13, the subject of Aspect 10 may optionally include that forming the second plate comprises: thinning the substrate on a side of the substrate which is opposite the first main surface of the substrate; and producing the second plate on a second main surface of the substrate produced by the thinning, wherein the capacitor dielectric is formed by a part of the substrate.

In Aspect 14, the subject of Aspect 13 may optionally include applying the substrate to a carrier which faces the second main surface of the substrate, in particular a glass carrier or silicon carrier.

In Aspect 15, the subject of one of Aspects 10 to 14 may optionally include that the forming of the first plate of the capacitor above the first main surface of the substrate comprises: depositing a superconducting metal layer above the first main surface of the substrate; and structuring the superconducting metal layer to produce the first plate of the capacitor.

In Aspect 16, the subject of Aspect 15 may optionally include that at least one further component of the superconducting electronic circuit unit is produced in the superconducting metal layer.

In Aspect 17, the subject of Aspect 16 may optionally include that the at least one further component is a Josephson contact and/or an inductor and/or a readout resonator.

In Aspect 18, the subject of one of Aspects 15 to 17 may optionally include forming vias in the substrate which electrically connect the superconducting metal layer to the second plate.

Although specific implementations have been described herein, a person skilled in the art will understand that a multiplicity of alternative and/or equivalent implementations can be used instead of the specific implementations described, without departing from the scope of application of the present implementation. This application is intended to cover all adaptations or variations of the specific implementations described herein. Therefore, the intention is for this implementation to be restricted only by the claims and the equivalents thereof.

1. An electronic circuit, comprising:
a substrate; and
a superconducting electronic circuit unit which is constructed on the substrate and comprises a capacitor with parallel plates opposite one another and a crystalline capacitor dielectric arranged between the parallel plates.

2. The electronic circuit as claimed in claim 1, wherein a part of the substrate forms the capacitor dielectric.

3. The electronic circuit as claimed in claim 1, wherein the capacitor dielectric comprises crystalline silicon or sapphire.

4. The electronic circuit as claimed in claim 1, wherein the superconducting electronic circuit unit comprises a resonant circuit that comprises the capacitor.

5. The electronic circuit as claimed in claim 1, wherein the superconducting electronic circuit unit comprises a resonant circuit and an electronic readout circuit, and
wherein the resonant circuit and the electronic readout circuit are coupled via the capacitor.

6. The electronic circuit as claimed in claim 4, wherein the resonant circuit contains a Josephson contact.

7. The electronic circuit as claimed in claim 6, wherein the resonant circuit constitutes a qubit.

8. The electronic circuit as claimed in claim 1, wherein, except for the capacitor, all of the components of the superconducting electronic circuit unit are arranged above a first main surface of the substrate.

9. The electronic circuit as claimed in claim 1, wherein the substrate is silicon-on-insulator (SOI) substrate that comprises a silicon layer above an oxide layer, and
wherein the capacitor dielectric is formed by a part of the silicon layer.

10. A method for producing an electronic circuit, the method comprising:
providing a substrate;
forming a first plate of a capacitor above a first main surface of the substrate;
forming a second plate of the capacitor which is opposite the first plate and parallel to the first plate, wherein a crystalline capacitor dielectric is present between the first plate and the second plate; and
forming a superconducting electronic circuit unit on the substrate, wherein the superconducting electronic circuit unit comprises the capacitor.

11. The method as claimed in claim 10, wherein forming the second plate comprises:
removing substrate material on a second main surface of the substrate in an area below the first plate in order to form a recess in the substrate on the second main surface, wherein the second main surface is arranged opposite to the first main surface of the substrate; and
producing the second plate in the recess.

12. The method as claimed in claim 11, wherein the substrate is a silicon-on-insulator (SOI) substrate that comprises a silicon layer above an oxide layer, and the removal of the substrate material comprises:
removing the substrate material starting from the second main surface of the substrate in the area below the first plate; and
removing the oxide layer in the area below the first plate.

13. The method as claimed in claim 10, wherein forming the second plate comprises:
thinning the substrate on a side of the substrate that is opposite to the first main surface of the substrate; and
producing the second plate on a second main surface of the substrate produced by the thinning, wherein the capacitor dielectric is formed by a part of the substrate.

14. The method as claimed in claim 13, further comprising:
applying the substrate to a carrier which faces the second main surface of the substrate.

15. The method as claimed in claim 10, wherein forming the first plate of the capacitor above the first main surface of the substrate comprises:
depositing a superconducting metal layer above the first main surface of the substrate; and
structuring the superconducting metal layer to produce the first plate of the capacitor.

16. The method as claimed in claim 15, wherein at least one further component of the superconducting electronic circuit unit is produced in the superconducting metal layer.

17. The method as claimed in claim 16, wherein the at least one further component is at least one of a Josephson contact, an inductor, or a readout resonator.

18. The method as claimed in claim 15, further comprising:
forming vias in the substrate which electrically connect the superconducting metal layer to the second plate.
